(19) United States
(12) Patent Application Publication
(10) Pub. No.: US 2018/0026646 A1
(43) Pub. Date: Jan. 25, 2018

(54) MULTIPLE-OUTPUT OSCILLATOR CIRCUITS

(71) Applicant: SanDisk Technologies LLC, Plano, TX (US)

(72) Inventors: Bhavin Odedara, Bangalore (IN); Srikanth Bojja, Bangalore (IN); Jayanth Mysore Thimmaiah, Bangalore (IN); Srinivasa Rao Sabbineni, Bangalore (IN)

(73) Assignee: SanDisk Technologies LLC, Plano, TX (US)

(21) Appl. No.: 15/218,638

(22) Filed: Jul. 25, 2016

(51) Int. Cl. H03L 7/099; H03L 7/093; H03B 27/00; H03L 7/089

(52) U.S. Cl. CPC H03L 7/099; H03L 7/0891; H03L 7/093; H03B 27/00

(57) ABSTRACT

A phase-locked loop (PLL) circuit may be configured to generate a plurality of oscillating signals based on a single control voltage generated based on a phase difference between an input signal and a feedback signal. One of the plurality of oscillating signals may be used to generate the feedback signal.

### BACKGROUND

In an electronic system, such as a system on a chip (SoC), different circuit components of the system may operate at different frequencies. In order to accommodate the different operating frequencies, the system may include multiple oscillators that generate different signals at the different frequencies and supply the signals to the system components. However, each oscillator may consume a certain amount of area and a certain amount of power. Since minimizing space and power consumption is typically desirable for electronic system design, ways to reduce the space and power that the oscillator circuitry consumes while maintaining the number of oscillating signals that the oscillator circuitry generates may be desirable.

### BRIEF DESCRIPTION OF THE DRAWINGS

The accompanying drawings, which are incorporated in and constitute a part of this specification illustrate various aspects of the invention and together with the description, serve to explain its principles. Wherever convenient, the same reference numbers will be used throughout the drawings to refer to the same or like elements.

FIG. 1 is a block diagram of an example phase-locked loop (PLL) circuit.

FIG. 2 is a block diagram of an example configuration for oscillation circuitry of the PLL circuit of FIG. 1.

FIG. 3 is a block diagram of another example PLL circuit.

FIG. 4 is a block diagram of an example configuration for oscillation circuitry of the PLL circuit of FIG. 3.

FIG. 5 is a block diagram of another example configuration of for the oscillation circuitry of the PLL circuit of FIG. 3.

FIG. 6 is a flow chart of an example method of generating a plurality of oscillating signals with a PLL circuit.

FIG. 7 is flow chart of a second example method of generating a plurality of oscillating signals with a PLL circuit.

FIG. 8 is a flow chart of a third example method of generating a plurality of oscillating signals with a PLL circuit.

### DETAILED DESCRIPTION OF PRESENTLY PREFERRED EMBODIMENTS

Overview

As mentioned in the background section, some systems may include multiple oscillators that generate different signals at the different frequencies and supply the signals to the system components. The present description describes various embodiments of a phase-locked loop (PLL) circuit that utilizes a single voltage control signal and a single feedback loop to generate and output multiple oscillating signals. In one embodiment, a circuit includes: phase detection circuitry configured to generate a control signal corresponding to a phase difference between an input signal and a feedback signal; and oscillation circuitry configured to generate a plurality of oscillating signals, each generated based on the control signal.

In some embodiments, a feedback path is configured to generate the feedback signal, wherein the feedback path is configured to receive one and less than all of the plurality of oscillating signals to generate the feedback signal.

In some embodiments, the feedback path is configured to receive only one of the plurality of oscillating signals to generate the feedback signal.

In some embodiments, the oscillation circuitry includes a plurality of chains of delay cell circuits, where each of the plurality of chains is configured to generate a respective one of the plurality of oscillating signals based on the control signal.

In some embodiments, the oscillation circuitry further includes current generation circuitry configured to: receive the control signal, generate a plurality of currents based on the control signal, and supply the plurality of currents to the plurality of chains, where each of the plurality of oscillating signals is generated based on one of the plurality of currents.

In some embodiments, the current generation circuitry is configured to generate at least one of the plurality of currents at a different amount than another of the plurality of currents in response to receipt of the control signal.

In some embodiments, the control signal comprises a first control signal, and the current generation circuitry is further configured to: receive one or more second control signals, and generate one or more of the plurality of currents further based on the one or more second control signals.

In some embodiments, each of the plurality of chains comprises a same number of delay circuits.

In some embodiments, at least one of the plurality of chains comprises a different number of delay cell circuits involved in generation of a respective one of the plurality of oscillating signals than another of the plurality of chains.

In some embodiments, chain control circuitry is configured to dynamically set a number of delay cell circuits involved in generation of a respective one of the plurality of oscillating signals for at least one of the plurality of chains.

In a second embodiment, a circuit includes a plurality of oscillation circuits. Each of the plurality of oscillation circuits is configured to generate one of a plurality of oscillating signals. In addition, each of the plurality of oscillation circuits is configured to: receive a common control signal that is common to the plurality of oscillation circuits and a respective one of the plurality of tuning control signals; and generate a respective one of the plurality of oscillating signals based on the common control signal and the respective one of the plurality of tuning control signals.

In some embodiments, the control signal is based on a phase difference between an input signal and a feedback signal that is generated based on one of the plurality of oscillating signals.

In some embodiments, current generation circuitry is configured to: receive the plurality of tuning control signals; generate a plurality of currents, each based on the plurality of tuning control signals; and supply the plurality of currents to the plurality of oscillation circuits, where amounts of the plurality of currents are based on values of the tuning control signals.

In some embodiments, e circuit of claim 11, chain control circuitry is configured to receive the plurality of tuning control signals, and set numbers of delay cell circuits involved in generation of the plurality of oscillation signals in response to values of the tuning control signals.

In some embodiments, each of the plurality of oscillation circuits includes a voltage controlled oscillator comprising a voltage-to-current converter and a current controlled oscillator.

In a third embodiment, a method of oscillating signal generation is performed. The method includes: receiving, with oscillation circuitry, a common control signal corresponding to a phase difference between an input signal and a feedback signal; generating, with the oscillation circuitry, each of a plurality of oscillating signals based on the common control signal; receiving, with the oscillation circuitry, a tuning signal; and tuning, with the oscillation circuitry, a frequency of one of the plurality of oscillating signals based on the tuning signal.

In some embodiments, the method further includes: receiving, with a divider circuit, one of the plurality of oscillating signals; and dividing, with the divider circuit, the one of the plurality of oscillating signals by a divider value to generate the feedback signal.

In some embodiments, the oscillation circuitry includes a plurality of chains of delay cell circuits, each configured to generate a respective one of the plurality of oscillating signals, and the method further includes: generating, with current generation circuitry, each of a plurality of currents based on the common control signal, and supplying, with the current generation circuitry, the plurality of currents to the plurality of chains in order to generate the plurality of oscillating signals.

In some embodiments, the method further includes: receiving, with the current generation circuitry, the tuning signal, and generating, with the current generation circuitry, one of the plurality of currents based on the tuning signal, where tuning the frequency of the one of the plurality of oscillating signals is based on the generating of the one of the plurality of currents.

In some embodiments, the method further includes: receiving, with a chain control circuit, the tuning signal; and for one of the plurality of chains, setting, with the control circuit, a number of the delay circuits involved in generating a respective one of the plurality of oscillating signals based on the tuning signal.

In a fourth embodiment, a circuit includes: means for generating a control signal corresponding to a phase difference between an input signal and a feedback signal; and means for generating a plurality of oscillating signals, each generated based on the control signal.

Other embodiments are possible, and each of the embodiments can be used alone or together in combination. Accordingly, various embodiments will now be described with reference to the attached drawings.

### Exemplary Embodiments

As mentioned in the background section, an electronic system, such as a system on a chip (SoC), may include multiple components that operate at different frequencies. The present description describes various embodiments of a phase-locked loop (PLL) circuit that utilizes a single voltage control signal and a single feedback loop to generate and output multiple oscillating signals. The embodiments described may reduce the amount of area and power consumed compared to other oscillator circuits that have a one-to-one correspondence between the number of oscillating signals that are generated and the number of voltage control signals and/or the number of feedback loops. Also, as described in further detail below, those oscillating signals that are not part of the feedback loop may be generated with relatively low noise and jitter.

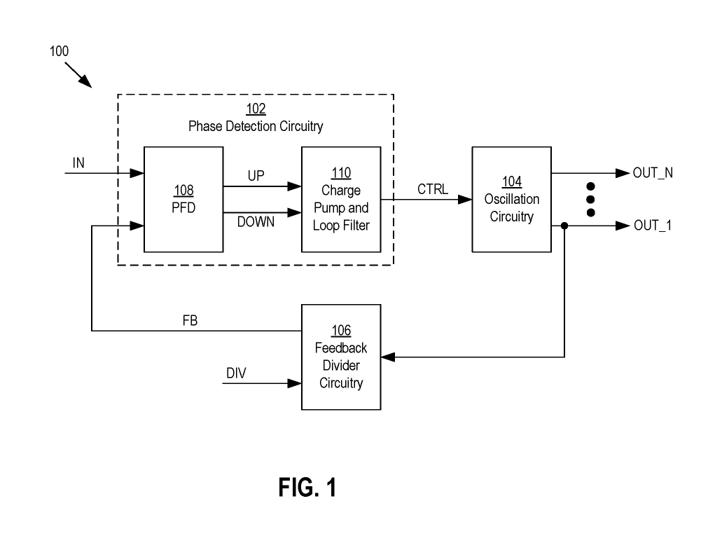

FIG. 1 shows a block diagram of an example phase-locked loop (PLL) circuit 100. The PLL circuit 100 may include phase detection circuitry 102, oscillation circuitry 104, and feedback divider circuitry 106. In general, the oscillation circuitry 104 may be configured to generate an N-number of oscillating signals OUT_1 to OUT_N, where N is two or more. Each of the oscillation signals OUT_1 to OUT_N may have an associated frequency. The phase detection circuitry 102 may be configured to generate a control signal CTRL based a phase difference between an input signal IN and a feedback signal FB, and send the control signal CTRL to the oscillation circuitry 104 for generation of the oscillating signals OUT_1 to OUT_N. A level of the control signal CTRL may determine, at least in part, the frequencies of each of the oscillation signals OUT_1 to OUT_N. In an example configuration, the oscillation circuitry 104 may be voltage controlled oscillation (VCO) circuitry and the control signal CTRL is a voltage signal, such that the voltage level of the control signal CTRL determines, at least in part, the frequencies of the oscillation signals OUT_1 to OUT_N.

The phase detection circuitry 102 may receive the input signal IN from a reference generator (e.g., a crystal oscillator), and the feedback signal FB from the feedback divider circuitry 106. The feedback divider circuitry 106 may be part of a feedback path of the PLL circuit 100. As shown in FIG. 1, one of the oscillating signals OUT_1 to OUT_N (e.g., OUT_1 in FIG. 1) may be sent to the feedback path in addition to being sent to a circuit or system component using the oscillating signal, while the other of the oscillating signals OUT_1 to OUT_N may not be part of the feedback. As previously described, by utilizing a single feedback path while generating multiple oscillating signals, the PLL configuration shown in FIG. 1 may consume less space or area compared to other PLL configurations that utilize one feedback path per oscillating signal.

The feedback divider circuitry 106 of the single feedback path may receive the one of the plurality of oscillating signals (e.g., OUT_1), and divide the frequency of the oscillating signal OUT_1 by a divider value DIV. The divider value DIV may be an integer value or a non-integer value, depending on the implementation. In general, the divider value DIV may correspond to and/or be equal to a ratio of a frequency of the oscillating signal OSC_1 to the frequency of the input signal IN. In some example configurations, the divider value DIV may be a n-bit binary value, although other configurations of the divider value DIV may be possible.

In some example configurations, the oscillation circuitry 104 responds such that an increase in the level of the control signal CTRL increases the frequencies of the oscillating signals OUT_1 to OUT_N, and a decrease in the level of the control signal CTRL decreases the frequencies of the oscillating signals OUT_1 to OUT_N. Also, in some example configurations, the input signal IN leading the feedback signal FB (the feedback signal FB lagging the input signal IN) may indicate to increase the frequencies of the oscillating signals OUT_1 to OUT_N. Accordingly, based on a detection that the input signal IN is leading the feedback signal FB, the phase detection circuitry 102 may proportionately increase the level of the control signal CTRL. Alternatively, the input signal IN lagging the feedback signal FB (the feedback signal FB leading the input signal IN) may indicate to decrease the frequencies of the oscillating signals OUT_1 to OUT_N. Accordingly, based on a detection that the input signal IN is lagging the feedback signal FB, the phase detection circuitry 102 may proportionately decrease the level of the control signal CTRL.

In a particular example configuration as shown in FIG. 1, the phase detection circuitry 102 may include a phase-frequency detector (PFD) circuit component 108 and a charge pump and loop filter circuit component 110. The PFD circuit 108 may receive the input signal IN and the feedback signal FB and detect the phase difference between the input signal IN and the feedback signal FB. For some example configurations, the input signal IN and the feedback signal FB may both be clock signals, although other types of oscillating or periodic signals may be possible. The charge pump may be configured to generate and supply a current to a capacitor of the loop filter, which in turn may generate the control signal CTRL in response to the current. Accordingly, the level of the control signal CTRL may depend on the current supplied by the charge pump. In some example configurations, the number N (i.e., the number of oscillating signals OUT_1 to OUT_N that may be generated) may depend on an output capacitance of the charge pump and/or a capacitance of the loop filter circuitry

Based on the phase relationship between the input signal IN and the feedback signal FB, the PFD circuit 108 may determine to generate and send an up signal UP to the charge pump to increase the current supplied by the charge pump or send a down signal DOWN to the charge pump to decrease the current. Sending the up signal UP may increase the level of the control signal CTRL, which in turn may increase the frequencies of the output signals OUT_1 to OUT_N. Conversely, sending the down signal DOWN may decrease the level of the control signal CTRL, which in turn may decrease the frequencies of the output signals OUT_1 to OUT_N.

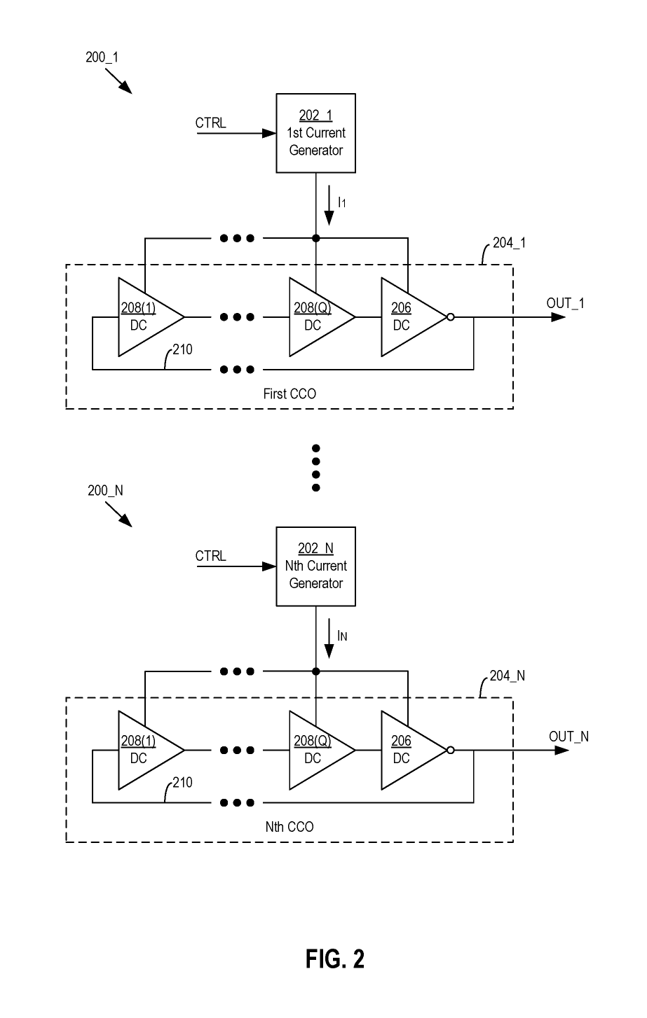

FIG. 2 is a block diagram of an example configuration for the oscillation circuitry 104 of the PLL circuit 100 of FIG. 1. The example configuration may include an N-number of oscillation circuits 200_1 to 200_N, each configured to generate and output a respective one of the oscillating signals OUT_1 to OUT_N. Each oscillation circuit 200 may include a current generator 202 and a chain 204 of delay cell (DC) circuits. Each of the current generators 202_1 to 202_N may be configured to supply a current I to the delay cells of an associated 204. Each of the chains 204_1 to 204_N may be configured to output one of the plurality of oscillating signals OUT_1 to OUT_N.

In general, each delay cell may provide an associated phase delay, and the amount of phase delay of each delay cell in a chain 204 along with the number of phase delay cells in the chain 204 may determine the frequency of the oscillating signal that is output by the chain 204. The phase delay provided by a delay cell may depend on the amount of the current I it receives from the current generator 202. Accordingly, changing the amount of the current I may change the amount of phase delay provided by a delay cell.

In addition, as shown in FIG. 2, each of the current generators 202_1 to 202_N may receive the control signal CTRL. A level of the control signal CTRL may determine the amount of current that each of the current generators 202_1 to 202_N outputs. Accordingly, the phase detection circuitry 102 (FIG. 1) may be configured to output the control signal CTRL at a level to cause the current generators 202_1 to 202_N to output respective currents I₁ to I_{N} to associated chains 204_1 to 204_N in order to cause the chains 204_1 to 204_N to output their respective oscillating signals OUT_1 to OUT_N at desired frequencies. Similarly, changing the level of the control signal CTRL may change the amount of current each of the current generators 202 outputs, which in turn may correspondingly change the frequencies of the oscillating signals OUT_1 to OUT_N.

For configurations where the control signal CTRL is a voltage signal, the current generators 202_1 to 202_N may be voltage-to-current converters. Also, by being dependent on the current supplied from the current generators 202, the chains 204 may be current-controlled oscillators (CCO), as indicated in FIG. 2. A combination of a voltage-to-current converter 202 and a current-controlled oscillator 204 may form a voltage-controlled oscillator (VCO). In other words, for the configuration shown in FIG. 2, each of the oscillation circuits 200_1 to 200_N may be configured as voltage-controlled oscillators. In this way, the example PLL circuit 100 of FIG. 1 may be considered a PLL circuit that includes multiple VCOs and a single feedback loop. Such a PLL configuration may be in contrast to other PLL configurations that utilize multiple feedbacks loops for multiple VCOs.

As previously described with reference to FIG. 1, one of the oscillating signals OUT_1 to OUT_N may be fed back for generation of the feedback signal FB, while the other oscillating signals may not. As a result, for those oscillation circuits 200_1 to 200_N that do not provide an oscillating signal to the feedback path, the internal capacitances of those oscillation circuits 200_1 to 200_N, such as the output capacitances of their current generators 202, may not affect the stability of the feedback path. In turn, those oscillating signals that are not provided to the feedback path of the PLL circuit 100 may have relatively low noise and/or jitter.

As mentioned, each of the delay cells of a chain 204 may provide an associated phase delay. An example circuit configuration for a delay cell may be a buffer or an inverter, although other circuit configurations are possible. Additionally, each of the chains 204_1 to 204_N may include an output delay cell 206 configured to output a respective one of the oscillating signals OUT_1 to OUT_N, and a Q-number of preceding delay cells 208(1) to 208(Q). For the configuration shown in FIG. 2, the output delay cell 206 may be an inverting delay cell and the preceding delay cells 208(1) to 208(Q) may be non-inverting delay cells, although other inverting and non-inverting configurations may be possible. The output delay cell 206 may be configured to generate and output an associated one of the oscillating signals OUT_1 to OUT_N. Additionally, the associated oscillating signal may be fed back to an input of a first or initial delay cell 208(1) via a feedback connection 210.

For the PLL circuit 100, the frequencies of the oscillating signals OUT_1 to OUT_N may be the same or different from each other. For example, all of the oscillating signals OUT_1 to OUT_N may have the same frequency, all of the oscillating signals OUT_1 to OUT_N may have different frequencies from each other, or some of the frequencies may be the same while others are different from each other. Various configurations are possible and may depend on the system in which the PLL circuit 100 is implemented and the frequencies at which the components of the system operate. In order for the chains 204_1 to 204_N to generate frequencies as accurately or in as controlled of an environment as possible, it may be desirable for the delay cells of the different chains 204_1 to 204_N to be matched with appropriate layout matching, such as by placing the oscillation circuits 200_1 to 200_N closely on the same chip.

As mentioned, the frequencies at which the oscillating signals OUT_1 to OUT_N are generated may depend on the amount of the currents supplied from the current generators 202 and the number of delay cells in each of the chains 204. Accordingly, for two oscillation circuits 200 to output oscillating signals with the same frequency, their respective chains 204 may include the same number of delay cells and their respective current generators 202 may be configured to generate the same amount of current in response to the control signal CTRL. Alternatively, for two oscillation circuits 200 to output oscillating signals with different frequencies, their respective chains may include different numbers of delay cells (e.g., the number Q may be different for the two delay chains 204), their respective current generators 202 may be configured to generate different amounts of current in response to the control signal CTRL, or a combination thereof.

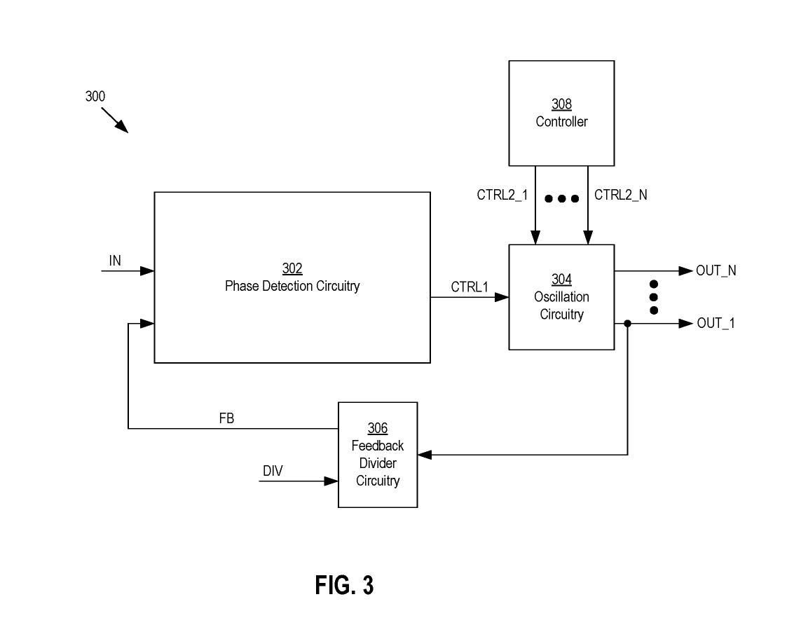

The PLL circuit 100 and the example configuration of the oscillation circuitry 104 as shown and described with reference to FIGS. 1 and 2 may be considered a static configuration in that the frequencies of the oscillating signals OUT_1 to OUT_N may be static or fixed for a given level of the control signal CTRL. FIG. 3 shows another example PLL circuit 300. In contrast to the example PLL circuit 100 of FIG. 1, the example PLL circuit 300 of FIG. 3 may be dynamic or programmable. In particular, the example PLL circuit 300 may use one or more second control signals to set, tune, program, and/or adjust one or more frequencies of the oscillating signals OUT_1 to OUT_N.

Like the PLL circuit 100 of FIG. 1, the PLL circuit 300 may include phase detection circuit 302, oscillation circuitry 304, and feedback divider circuitry 306. The oscillation circuitry 304 may be configured to generate and output a plurality of oscillating signals OUT_1 to OUT_N. The phase detection circuitry 302 and the feedback divider circuitry 306 may be implemented and/or configured to operate in the same way as the phase detection circuitry 102 and the feedback divider circuitry 106 of FIG. 1, respectively. For the PLL circuit 300 of FIG. 3, the control signal output by the phase detection circuitry 302 to the oscillation circuitry 304 may be referred to as a first control signal CTRL1.

In addition to receipt of the first control signal CTRL1, the oscillation circuitry 304 may be configured to receive one or more second control signals CTRL2 used to set and/or adjust one or more frequencies of the oscillating signals OUT_1 to OUT_N. The number of second control signals CTRL2 received by the oscillation circuitry 304 may correspond to the number frequencies to be independently set with the second control signals CTRL2. For example, FIG. 3 shows the oscillation circuitry 304 receiving an N-number of second control signals CTRL2_1 to CTRL_N in order for each of the N-number of oscillating signals OUT_1 to OUT_N to be independently set. However, for other example configurations, fewer than N second control signals CTRL2 may be received in order for fewer than all N of the oscillating signals OUT_1 to OUT_N to be independently set. Also, as shown in FIG. 3, a controller circuit 308, which may implemented in hardware or a combination of hardware and software, may be configured to generate and output the one or more second control signals CTRL2 to the oscillation circuitry 304. The controller 308 may be considered part of the PLL circuit 300, external from PLL circuit 300, part of the same system (e.g., system on a chip) as the PLL circuit 300, or external from the system in which the PLL circuit 300 is implemented. Various implementations of the controller 308 in conjunction with the PLL circuit 300 are possible.

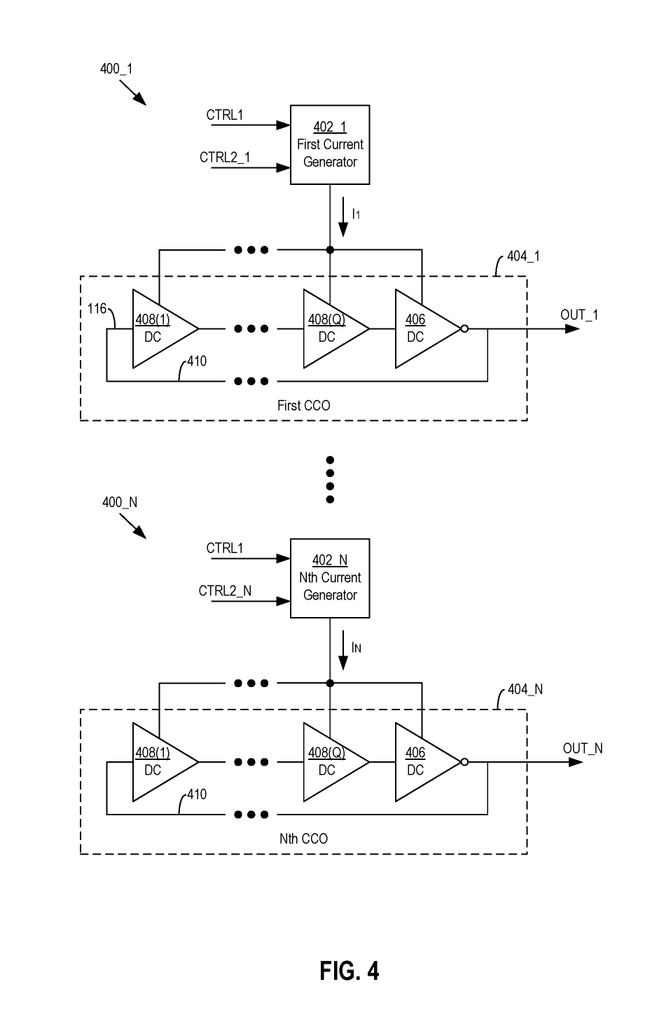

FIG. 4 shows a block diagram of an example configuration of the oscillation circuitry 304. Similar to the configuration of the oscillation circuitry 104 shown in FIG. 2, the configuration shown in FIG. 4 includes an N-number of oscillation circuits 400_1 to 400_N, each configured to generate one of the oscillating signals OUT_1 to OUT_N. Additionally, each of the oscillation circuits 400_1 to 400_N includes a current generator 402 and a chain 404 of delay cell circuits, including an output delay cell 406, a Q-number of preceding delay cells 408(1) to 408(Q), and a feedback connection 410 connecting an output of the output delay cell 406 to an input of a first or initial delay cell 408(1). Also, each of the current generators 402_1 to 402_N may be configured to receive the first control signal CTRL1 from the phase detection circuitry 302 and supply a current I to an associated chain 404.

For the configuration shown in FIG. 4, each of the N current generators 402_1 to 402_N may also be configured to receive one of the second control signals CTRL2_1 to CTRL2_N. The amount of current each of the current generators 402_1 to 402_N supplies may further be dependent upon the second control signal CTRL2 that it receives. In some example configurations, the second control signals CTRL2 may be n-bit digital signals, and their values may determine the amount of current each of the current generators 402_1 to 402_N supplies. By sending second control signals CTRL2 to the current generators 402, the PLL circuit 300 may be dynamic or programmable in that the controller 308 may be configured to set or adjust the second controls CTRL2_1 to CTRL2_N in order to set or adjust the amounts of the currents supplied to the delay cells of the chains 404, which in turn sets or adjusts the frequencies of the oscillating signals OUT_1 to OUT_N.

For some example configurations, the second control signals CTRL2 may be the sole factor in setting the frequencies of one or more of the oscillating signals OUT_1 to OUT_N different from one another. In particular, the current generators 402_1 to 402_N may be configured to generate the same amount of current I with respect to the first control signal CTRL1 and the number of delay cells in each of the chains 404_1 to 404_N may be the same. Accordingly, setting values for the control signals CTRL_1 to CTRL_N to be the same or different from one another may determine whether the corresponding chains 404_1 to 404_N output respective oscillating signals OUT_to OUT_N at the same or different frequencies. In other example configurations, the second control signals CTRL2 may not be the sole factor. For these other example configurations, at least two of the current generators 402_1 to 402_N may be configured to respond differently to the first control signal CTRL1 and/or the number of delay cells in at least two of the chains 404 may be different from one another in order for at least two of the chains 404 to output respective oscillating signals at different frequencies.

In addition, FIG. 4 shows each of the current generators 402_1 to 402_N as being configured to receive one of the N-number of second control signals CTRL2_1 to CTRL_N. In this way, each of the oscillating signals OUT_1 to OUT_N may be set and/or adjusted with an associated one of the second control signals CTRL2_1 to CTRL2_N, as previously described. In other example configurations, fewer than all of the N-number of current generators 402_1 to 402_N may be configured to receive a second control signal CTRL2. That is, at least one of the oscillating signals OUT_1 to OUT_N may not be set by a second control signal CTRL2. For these other configurations, at least one of the current generators 402_1 to 402_N may receive both the first control signal CTRL1 and a second control signal CTRL2, while at least one other of the current generators 402_1 to 402_N may receive only the first control signal CTRL1.

In sum, the N-number of oscillation circuits 400_1 to 400_N may be configured in various ways in order to output the N-number of oscillating signals OUT_1 to OUT_N at desired frequencies. Factors associated with the oscillation circuits 400_1 to 400_N that may be determined in order for the oscillating signals OUT_1 to OUT_N to be output at desired frequencies include: the number of current generators 402 receiving a second control signal CTRL2; the values of the second control signals CTRL2; the levels at which the current generators 402 supply their respective currents in response to the levels and/or values of the first control signal CTRL1 and/or a second control signal CTRL2; and the number of delay cells in each of the chains 404_1 to 404_N.

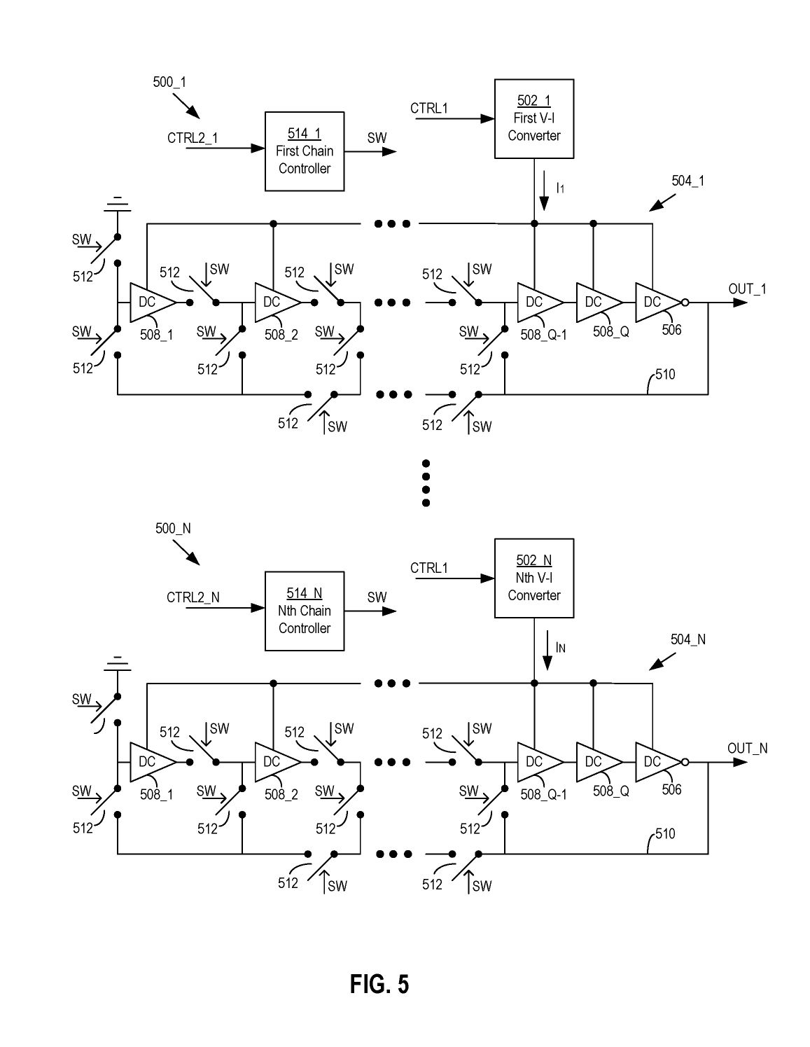

FIG. 5 shows a block diagram of another example configuration of the oscillation circuitry 304. Similar to the configurations shown in FIGS. 2 and 4, the configuration shown in FIG. 5 includes an N-number of oscillation circuits 500_1 to 500_N, each configured to generate one of the oscillating signals OUT_1 to OUT_N. Additionally, each of the oscillation circuits 500_1 to 500_N includes a current generator 502 and a chain 504 of delay cell circuits, including an output delay cell 506, a Q-number of preceding delay cells 508(1) to 508(Q), and a feedback connection 510 connecting an output of the output delay cell 506 to an input of a first or initial delay cell 508(1). Also, each of the current generators 502_1 to 502_N may be configured to receive the first control signal CTRL1 from the phase detection circuitry 302 and supply a current I to an associated chain 504.

With the example configuration of FIG. 5, the PLL circuit 300 may be dynamic or programmable in that for each of the chains 504_1 to 504_N, the number of delay cells involved in the generation of a respective one of the oscillating signals OUT_1 to OUT_N may be set and/or adjusted based on a second control signal CTRL2. As shown in FIG. 5, each of the chains 504_1 to 504_N may include switches 512 coupled to the inputs and outputs of at least some of the delay cells 508 and the feedback connection 510. The configuration of the switches 512 in each of the chains 504_1 to 504_N shown in FIG. 5 is merely exemplary and other types of configurations may be possible. In general, each of the chains 504_1 to 504_N may include three delay cells involved in the generation of an associated oscillating signal, including the associated output delay cell 506 and the two directly preceding delay cells 508_Q and 508_Q−1, at any given time. The switches 512 may then be configured to selectively or dynamically connect and disconnect none or one or more of the other preceding delay cells 508_1 to 508_Q−2 to the other three delay circuits for generation of the associated oscillating signal. In particular, for each of the chains 504_1 to 504_N, various combinations of the switches 512 being configured in opened and closed states may set and/or adjust which of the delay cells 508_1 to 508_Q−2 are connected to and which are disconnected from the respective chain 504, which in turn sets the number of the delay cells 508 that are involved in the generation of the associated oscillating signal. Also, the switches 502 may be configured in their respective opened and closed states such that each delay cell 508 that is not connected to associated chain 504 (or not involved in the generation of the associated oscillating signal) has its input connected to ground. Alternative configurations may configure the switches 512 to connect the inputs of the unconnected delay cells 508 to a supply voltage. Such connections may be made in order to avoid floating gates in the unconnected delay cells 508.

In the example configuration shown in FIG. 5, a chain controller 514 may be associated with and/or included in each of the oscillation circuits 500_1 to 500_N. Each of the chain controllers 514_1 to 514_N may be configured to receive an associated one of the second control signals CTRL2_1 to CTRL2_N. Additionally, each of the second control signals CTRL2_1 to CTRL2_N may indicate a number of delay cells of a chain 504 to be involved in the generation of an associated oscillating signal. For each of the oscillation circuits 500_1 to 500_N, based on the value of the second control signal CTRL2, the chain controller 514 may be configured to output a set of switching signals SW that configures each of the switches 512 of the associated chain 504 in an open or closed state in order to set the number of delay cells 508 connected to the chain 504 and involved in the generation of an associated oscillating signal.

Variations of the example configuration shown in FIG. 5 are possible. For example, at least one but less than all of the chains 504_1 to 504_N may be configured with an adjustable number of delay cells to be involved in the generation of an associated oscillating signal. For example, one or more of the oscillation circuits 504_1 to 504_N may be configured in accordance with the configuration of FIG. 2 and/or one or more of the oscillation circuits 504_1 to 504_N may be configured in accordance with the configuration of FIG. 4. In addition or alternatively, for each of the chains 504_1 to 504_N, the number of delay cells than can possibly or that are available to be involved in the generation of an oscillating signal may be the same as or different from each other. Various configurations or combinations of configurations may be possible.

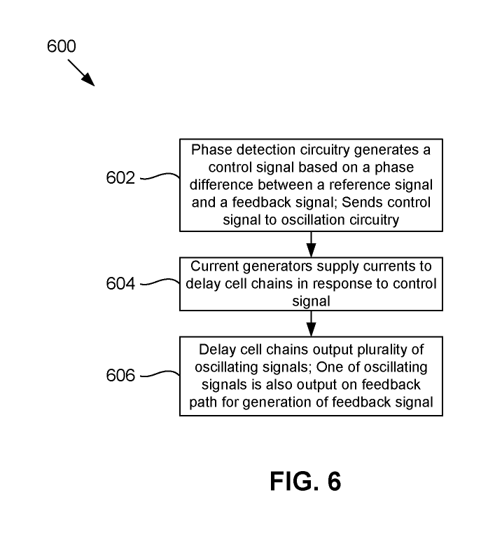

FIG. 6 shows a flow chart of an example method 600 of generating a plurality oscillating signals, such as with a PLL circuit as previously described. At block 602, phase detection circuitry may generate a control signal based on a phase difference between an input or reference signal and a feedback signal. For some example configurations, the phase detection circuitry may include a phase-frequency detector (PFD) that detects the phase difference and based on the difference, controls a supply of current to a capacitor by a charge pump in order to generate the control signal, as previously described. The control signal may be sent to oscillation circuitry for generation of the plurality of oscillating signals.

At block 604, current generation circuitry including a plurality of current generators may receive the control signal, and in response, supply currents to a plurality of chains of delay cell circuits. The level of the control signal may determine the amounts of the currents that are supplied. At block 606, each of the chains may output one of the plurality of oscillating signals. The frequency of each of the oscillating signals may depend on the number of delay cells of the chain generating the oscillating signal and the amount of current being supplied to the chain. The oscillating signals may be sent to respective circuit components of a system using the different oscillating signals to operate. Also, at block 606, one of the plurality of oscillating signals may also be output on a feedback path for generation of the feedback signal. For example, a frequency divider circuit may receive the one oscillating signal and divide a frequency of the oscillating signal by a divider value in order to generate the feedback signal.

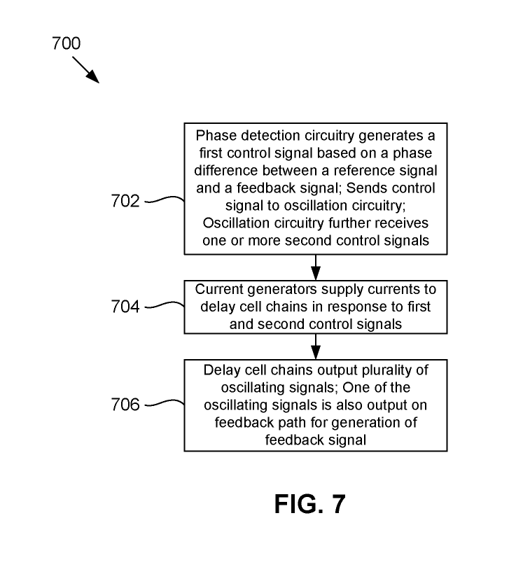

FIG. 7 shows a flow chart of another example method 700 of generating a plurality of oscillating signals, such as with a PLL circuit previously described. At block 702, phase detection circuitry may generate a first control signal based on a phase difference between a reference signal and a feedback signal. For some example configurations, the phase detection circuitry may include a phase-frequency detector (PFD) that detects the phase difference and based on the difference, controls a supply of current to a capacitor by a charge pump in order to generate the first control signal, as previously described. The first control signal may be sent to oscillation circuitry for generation of the plurality of oscillating signals. Additionally, the oscillation circuitry may further receive one or more second control signals for generation of the plurality of oscillating signals.

At block 704, current generators may receive the first control signal. In addition, one or more of the current generators may receive the one or more second control signals. Each of the current generators may supply a current to an associated chain of delay cell circuits based on the first control signal. For current generators receiving only the first control signal, each of those current generators may supply a current at a level based on the first control signal. For current generators receiving both the first control signal and a second control signal, each of those current generators may supply a current at a level based on both the first control signal and a respective one of the second control signals.

At block 706, each of the chains may output one of the plurality of oscillating signals. The frequency of each of the oscillating signals may depend on the number of delay cells of the chain generating the oscillating signal and the amount of current being supplied to the chain. The plurality of oscillating signals may be sent to respective circuit components of a system using the different oscillating signals. Also, at block 706, one of the plurality of oscillating signals may also be output on a feedback path for generation of the feedback signal. For example, a frequency divider circuit may divide a frequency of the oscillating signal by a divider value in order to generate the feedback signal.

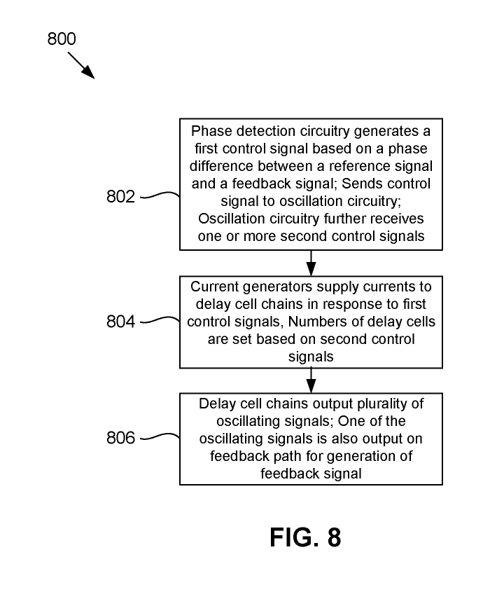

FIG. 8 shows a flow chart of another example method 800 of generating a plurality of oscillating signals, such as with a PLL circuit previously described. At block 802, phase detection circuitry may generate a first control signal based on a phase difference between a reference signal and a feedback signal. For some example configurations, the phase detection circuitry may include a phase-frequency detector (PFD) that detects the phase difference and based on the difference, controls a supply of current to a capacitor by a charge pump in order to generate the first control signal, as previously described. The first control signal may be sent to oscillation circuitry for generation of the plurality of oscillating signals. Additionally, the oscillation circuitry may further receive one or more second control signals for generation of the plurality of oscillating signals.

At block 804, current generators may receive the first control signal. In response, each of the current generators may supply a current to an associated chain of delay cell circuits based on the first control signal. In addition, the one or more second control signals may set the number of delay cells involved in the generation of an oscillating signal for one or more of the chains. In some methods, one or more chain controllers may receive the one or more second control signals and in response, output switching signals to associated chains to set the number of delay cells to be involved in the generation of oscillating signals.

At block 806, each of the chains may output one of the plurality of oscillating signals. The frequency of each of the oscillating signals may depend on the number of delay cells of the chain generating the oscillating signal and the amount of current being supplied to the chain. The plurality of oscillating signals may be sent to respective circuit components of a system using the different oscillating signals. Also, at block 806, one of the plurality of oscillating signals may also be output on a feedback path for generation of the feedback signal. For example, a frequency divider circuit may divide a frequency of the oscillating signal by a divider value in order to generate the feedback signal.

The above example methods described with reference to FIGS. 6-8 are non-limiting and other methods implementing the actions described with reference to FIGS. 6-8 may be possible. For example, another example method may utilize second control signals to generate one or more currents with current generators and also to set the number delay cells used to generate an oscillating signal for one or more of chains.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the preferred embodiments described herein can be used alone or in combination with one another.

We claim:

1. A circuit comprising:
phase detection circuitry configured to generate a control signal corresponding to a phase difference between an input signal and a feedback signal; and
oscillation circuitry configured to generate a plurality of oscillating signals, each generated based on the control signal.

2. The circuit of claim 1, further comprising a feedback path configured to generate the feedback signal, wherein the feedback path is configured to receive one and less than all of the plurality of oscillating signals to generate the feedback signal.

3. The circuit of claim 1, wherein the feedback path is configured to receive only one of the plurality of oscillating signals to generate the feedback signal.

4. The circuit of claim 1, wherein the oscillation circuitry comprises a plurality of chains of delay cell circuits, each of the plurality of chains configured to generate a respective one of the plurality of oscillating signals based on the control signal.

5. The circuit of claim 4, wherein the oscillation circuitry further comprises current generation circuitry configured to:
receive the control signal;
generate a plurality of currents based on the control signal; and
supply the plurality of currents to the plurality of chains, wherein each of the plurality of oscillating signals is generated based on one of the plurality of currents.

6. The circuit of claim 5, wherein the current generation circuitry is configured to generate at least one of the plurality of currents at a different amount than another of the plurality of currents in response to receipt of the control signal.

7. The circuit of claim 5, wherein the control signal comprises a first control signal, and wherein the current generation circuitry is further configured to:
receive one or more second control signals; and
generate one or more of the plurality of currents further based on the one or more second control signals.

8. The circuit of claim 7, wherein each of the plurality of chains comprises a same number of delay circuits.

9. The circuit of claim 4, wherein at least one of the plurality of chains comprises a different number of delay cell circuits involved in generation of a respective one of the plurality of oscillating signals than another of the plurality of chains.

10. The circuit of claim 9, further comprising chain control circuitry configured to dynamically set a number of delay cell circuits involved in generation of a respective one of the plurality of oscillating signals for at least one of the plurality of chains.

11. A circuit comprising:
a plurality of oscillation circuits, each configured to generate one of a plurality of oscillating signals;
wherein each of the plurality of oscillation circuits is configured to:
receive a common control signal that is common to the plurality of oscillation circuits and a respective one of a plurality of tuning control signals; and
generate a respective one of the plurality of oscillating signals based on the common control signal and the respective one of the plurality of tuning control signals.

12. The circuit of claim 11, wherein the control signal is based on a phase difference between an input signal and a feedback signal that is generated based on one of the plurality of oscillating signals.

13. The circuit of claim 11, further comprising current generation circuitry configured to:
receive the plurality of tuning control signals;
generate a plurality of currents, each based on the plurality of tuning control signals; and
supply the plurality of currents to the plurality of oscillation circuits, wherein amounts of the plurality of currents are based on values of the tuning control signals.

14. The circuit of claim 11, further comprising:
chain control circuitry configured to receive the plurality of tuning control signals; and
set numbers of delay cell circuits involved in generation of the plurality of oscillation signals in response to values of the tuning control signals.

15. The circuit of claim 11, wherein each of the plurality of oscillation circuits comprises a voltage controlled oscillator comprising a voltage-to-current converter and a current controlled oscillator.

16. A method of oscillating signal generation comprising:
receiving, with oscillation circuitry, a common control signal corresponding to a phase difference between an input signal and a feedback signal;
generating, with the oscillation circuitry, each of a plurality of oscillating signals based on the common control signal;
receiving, with the oscillation circuitry, a tuning signal; and
tuning, with the oscillation circuitry, a frequency of one of the plurality of oscillating signals based on the tuning signal.

17. The method of claim 16, further comprising:
receiving, with a divider circuit, one of the plurality of oscillating signals; and
dividing, with the divider circuit, the one of the plurality of oscillating signals by a divider value to generate the feedback signal.

18. The method of claim 16, wherein the oscillation circuitry comprises a plurality of chains of delay cell circuits, each configured to generate a respective one of the plurality of oscillating signals, the method further comprising:
generating, with current generation circuitry, each of a plurality of currents based on the common control signal; and
supplying, with the current generation circuitry, the plurality of currents to the plurality of chains in order to generate the plurality of oscillating signals.

19. The method of claim 18, further comprising:
receiving, with the current generation circuitry, the tuning signal; and
generating, with the current generation circuitry, one of the plurality of currents based on the tuning signal,
wherein tuning the frequency of the one of the plurality of oscillating signals is based on the generating of the one of the plurality of currents.

20. The method of claim 18, further comprising:
receiving, with a chain control circuit, the tuning signal; and
for one of the plurality of chains, setting, with the control circuit, a number of the delay circuits involved in generating a respective one of the plurality of oscillating signals based on the tuning signal.

21. A circuit comprising:
means for generating a control signal corresponding to a phase difference between an input signal and a feedback signal; and
means for generating a plurality of oscillating signals, each generated based on the control signal.
